(19) United States
(12) Patent Application Publication
(10) Pub. No.: US 2026/0282815 A1
(43) Pub. Date: Sep. 17, 2026

(54) Substrate Processing Apparatus and Maintenance Method

(71) Applicant: SCREEN Holdings Co., Ltd., Kyoto (JP)

(72) Inventors: Takanori HIRAI, Kyoto-shi (JP); Kota YAMAGAMI, Kyoto-shi (JP)

(21) Appl. No.: 19/442,647

(22) Filed: Jan. 7, 2026

(30) Foreign Application Priority Data
Mar. 12, 2025 (JP) 2025-038930

(51) Int. Cl. H10P 72/00; H10P 72/76

(52) U.S. Cl. CPC H10P 72/0616; H10P 72/0432; H10P 72/7612

(57) ABSTRACT

A substrate processing apparatus has a correction mechanism that corrects warping of a substrate on a substrate support by bringing a correction member into contact with an upper surface of the substrate, by raising or lowering at least one of a correcting/supporting part and the substrate support while the correction member remains in a correction posture facing the substrate support. The correcting/supporting part is provided so as to be swingable about a first swing shaft extending in a first horizontal direction. The correcting/supporting part is switchable between the correction posture and a separation posture. In separation posture, the correction member is spaced upward from the substrate support with the opening opened by opening the lid part. Hence, a maintenance operation can be performed by accessing an internal space of the substrate processing apparatus without removing the correction mechanism from the apparatus.

### CROSS REFERENCE TO RELATED APPLICATION

The disclosure of Japanese Patent Application No. 2025-38930 filed on Mar. 12, 2025 including specification, drawings and claims is incorporated herein by reference in its entirety.

### BACKGROUND OF THE INVENTION

### 1. Field of the Invention

This invention relates to a substrate processing apparatus provided with a correction mechanism for not only performing a predetermined processing such as a heating process on a substrate stored in an internal space of a chamber body, but also correcting the warping of the substrate and a maintenance method for the substrate processing apparatus.

### 2. Description of the Related Art

In a manufacturing process of a semiconductor device, various processes are performed on a substrate stored in an internal space of a chamber body. These processes include, for example, a so-called heating process for heating the substrate from below while supporting the substrate substantially in a horizontal posture in the internal space of the chamber body. In this heating process, it is a problem that a substrate warping amount increases due to the enlargement of a substrate and a uniform heating process is difficult in a heating step in a semiconductor device manufacturing process using a manufacturing form called a panel level packaging (PLP). Accordingly, it has been proposed to use a correction technique, for example, described in JP 2020-47829A. In this correction technique, a picture frame-like supporting part is arranged to face a peripheral edge part of the upper surface of a substrate from above, and correction pins project downward from the lower surface of the supporting part and can contact the peripheral edge part. Before the substrate is heated, the peripheral edge part warped upward, out of the substrate, is corrected by the correction pins, and the upward warping of the peripheral edge part of the substrate during the heating of the substrate is restricted to control the posture of the substrate being heated.

### SUMMARY OF INVENTION

However, in the correction technique described in JP 2020-47829A, if the substrate is, for example, broken in the internal space of the chamber body, a maintenance operation such as an access to the internal space and the collection of the substrate by an operator is necessary. To perform this maintenance operation, the correction mechanism needs to be removed from the chamber body. This has been one of main causes leading to an efficiency reduction of the maintenance operation.

This invention was developed in view of the above problem and aims to improve the efficiency of a maintenance operation by facilitating an access to an internal space in a substrate processing apparatus provided with a correction mechanism in the internal space of a chamber body and a maintenance method for this substrate processing apparatus.

A first aspect of the invention is a substrate processing apparatus. The apparatus includes: a chamber body having an opening opened upward and an internal space capable of storing a substrate; a lid part configured to open and close the opening; a substrate support configured to support the substrate from below in the internal space; and a correction mechanism having a correcting/supporting part that is provided between the lid part and the substrate support and a correcting member that projects downward from the correcting/supporting part, wherein the correction mechanism is configured to correct warping of the substrate by bringing the correction member into contact with an upper surface of the substrate supported by the substrate support, by raising or lowering at least one of the correcting/supporting part and the substrate support while the correction member remains in a correction posture facing the substrate support, and the correcting/supporting part is provided so as to be swingable about a first swing shaft extending in a first horizontal direction, and is configured to be switchable between the correction posture and a separation posture in which the correction member is spaced upward from the substrate support with the opening opened by opening the lid part.

A second aspect of the invention is a maintenance method for the substrate processing apparatus. The method includes: opening the opening, switching the correcting/supporting part to the separation posture by swinging the correcting/supporting part about the first swing axis, and performing a maintenance operation by accessing the internal space through a gap formed between an opposite swing axis side end part of the correcting/supporting part and the opening.

In the invention thus configured, the correcting/supporting part can be switched between the correction posture and the separation posture by swinging about the first swing axis. In the separation posture, out of these, the correcting member is separated upward from the correcting/supporting part with the opening opened by opening the lid part. Thus, if a maintenance operation is necessary, the internal space becomes accessible via the opening by the opening of the lid part and a switch to the separation posture.

As described above, the maintenance operation can be performed by accessing the internal space without removing the correction mechanism from the chamber body. The efficiency of the maintenance operation can be improved by facilitating the access to the internal space in this way.

All of a plurality of constituent elements of each aspect of the present invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the present invention described above can be combined with some or all of technical features included in another aspect of the present invention described above to obtain one independent form of the present invention in order to solve some or all of the aforementioned problems or to achieve some or all of the effects described in this specification.

### BRIEF DESCRIPTION OF THE DRAWINGS

FIG. 1A is a perspective view schematically showing a substrate processing system equipped with a hot plate unit, which is one embodiment of a substrate processing apparatus according to the invention.

FIG. 1B is a plan view schematically showing the substrate processing system shown in FIG. 1A.

FIG. 2 is a diagram showing the configuration of the heating process group.

FIG. 3 is a perspective view showing the external structure of the hot plate unit as an example of the substrate processing apparatus according to the invention.

FIG. 4 is a schematic diagram showing the configuration of the hot plate HP.

FIG. 5 is a perspective view showing the configuration of the correction mechanism.

FIG. 6 is a flow chart showing one embodiment of a maintenance method according to the invention.

FIG. 7 is a diagram showing the postures of the lid part and the correcting/supporting part in one step of the maintenance method shown in FIG. 6.

### DETAILED DESCRIPTION OF THE PREFERRED EMBODIMENTS

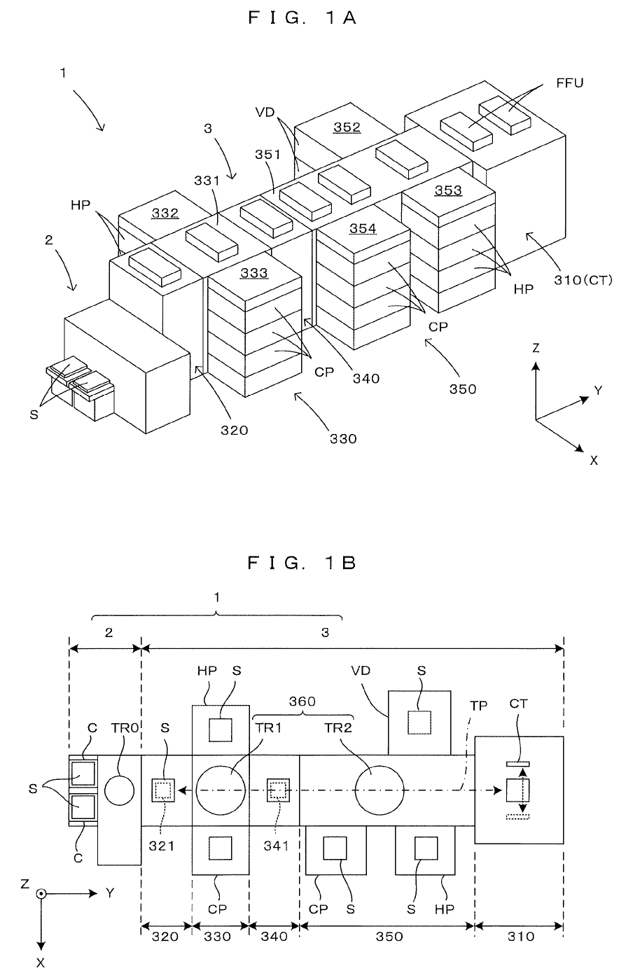

FIG. 1A is a perspective view schematically showing a substrate processing system equipped with a hot plate unit, which is one embodiment of a substrate processing apparatus according to the invention. Further, FIG. 1B is a plan view schematically showing the substrate processing system shown in FIG. 1A. The substrate processing system 1 is provided with a substrate carry-in/out device 2 for carrying in and out a substrate S and a substrate processing apparatus 3 for performing a coating process for applying a processing liquid to the substrate S received from the substrate carry-in/out device 2. The substrate carry-in/out device 2 includes a mechanism for transferring a cassette C on a front surface. Further, the substrate carry-in/out device 2 includes a conveyor robot TR0. This conveyor robot TR0 has a function of taking out the substrate S stored in the cassette C and transferring the substrate S to the substrate processing apparatus 3 and a function of receiving the substrate S treated by the coating process by the substrate processing apparatus 3 and returning the substrate S to the cassette C. Note that a coordinate system including a Z axis extending in a vertical direction and a XY plane as a horizontal plane is attached as appropriate to clarify the arrangement, the operation and the like of each component constituting the substrate processing system 1. A positive direction along the Z axis is a vertically upward direction.

The substrate processing apparatus 3 is arranged adjacent to a (+Y) direction side of the substrate carry-in/out device 2. In this substrate processing apparatus 3, a coating unit 310 is arranged at a position separated toward the (+Y) direction side from the substrate carry-in/out device 2. Further, a first standby unit 320, a pre-processing unit 330, a second standby unit 340 and a post-processing unit 350 are disposed in this order in a (+Y) direction between the substrate carry-in/out device 2 and the coating unit 310. Further, as shown by a one-dot chain line in FIG. 1B, a linear conveyance path TP extends in a Y direction inside those units, and a substrate conveyor 360 (FIG. 1B) for reciprocating the substrate S along the conveyance path TP is provided inside the substrate processing apparatus 3.

As shown in FIG. 1A, in the coating unit 310, a coater CT is arranged in internal space where clean air fed from fan filter units FFU mounted on a ceiling surface generates a downflow. The coating unit CT has a configuration similar to the coating apparatus disclosed in, for example, JP 2022-131177 A. The coater CT moves in the Y direction while ejecting the processing liquid from a slit nozzle to supply the processing liquid to a surface of the substrate S, thereby forming a coating film. Such generation of a downflow of clean air in internal space also applies to the first standby unit 320, the pre-processing unit 330, the second standby unit 340, and the post-processing unit 350 described later.

The first standby unit 320 is provided adjacent to the substrate carry-in/out device 2. As shown in FIG. 1B, the first standby unit 320 has internal space where a first mount 321 is provided that is configured to allow the substrate S to be placed thereon temporarily. Thus, by actuating the transport robot TR0 in response to a command from a controller for controlling the substrate carry-in/out device 2, the substrate S stored in the cassette C is extracted and placed on the first mount 321. In this way, the substrate S before being subjected to the coating process and a predetermined pre-process and a predetermined post-process accompanying the coating process is temporarily put on standby. After being subjected to these processes described later, the substrate S is temporarily put on standby on the first mount 321. Then, the transport robot TR0 accesses the first mount 321 with appropriate timing, receives the substrate S, and returns the substrate S to the cassette C. In this way, the first standby unit 320 fulfills the function of transferring the substrate S smoothly between the substrate carry-in/out device 2 and the substrate processing apparatus 3 and adjusting takt time between these apparatuses.

The pre-processing unit 330, the second standby unit 340, and the post-processing unit 350 are connected continuously in the (+Y) direction with respect to the first standby unit 320. Of these units, the second standby unit 340 has a second mount 341 like the first standby unit 320. The second mount 341 is for temporarily putting the substrate S on standby after the substrate S is subjected to the pre-process by the pre-processing unit 330 or after the substrate S is subjected to the post-process by the post-processing unit 350 after implementation of the coating process on the substrate S. By doing so, the substrate S is transferred smoothly between the coating unit 310, the pre-processing unit 330, and the post-processing unit 350, and takt time is adjusted between these units.

The pre-processing unit 330 is arranged between the first and second standby units 320, 340. As shown in FIG. 1A, the pre-processing unit 330 is provided with a housing 331 functioning as a part of the conveyance path TP inside, a heating process group 332, in which hot plate units HP (hereinafter, merely referred to as “hot plates HP”) for dehydration baking the substrate S are stacked, and a cooling process group 333, in which cool plate units CP (hereinafter, merely referred to as “cool plates CP”) for cooling the substrate S after the dehydration baking are stacked. The housing 331 is provided adjacent to a first mounting table 321. Further, the heating process group 332 and the cooling process group 333 are sorted out for the housing 331 in the Y direction. More specifically, the heating process group 332 is arranged on a (-X) direction side of the housing 331, and the cooling process group 333 is arranged on a (+X) direction side. Further, a first conveyor robot TR1 is fixedly arranged in the housing 331. This first conveyor robot TR1 is configured such that a hand (not shown) capable of holding the substrate S is accessible to the first mounting table 321, the hot plates HP of the heating process group 332, the cool plates CP of the cooling process group 333 and the second mounting table 341. Therefore, the first conveyor robot TR1 operates in response to a command from a controller for controlling the substrate processing apparatus 3, whereby the substrate S is reciprocated along the conveyance path TP between the first mounting table 321 and the second mounting table 341 and conveyed among the first mounting table 321, the hot plates HP, the cool plates CP and the second mounting table 341. Note that, in this embodiment, the number of the hot plates HP in the heating process group 332 is “3” and the number of the cool plates CP in the cooling process group 333 is “3”. Those numbers are not limited to “3”, but arbitrary. Further, the numbers of the heating process groups 332 and the cooling process groups 333 are also arbitrary.

The post-processing unit 350 is arranged on a (+Y) direction side of the second standby unit 340 including the second mounting table 341. As shown in FIG. 1A, the post-processing unit 350 is provided with a housing 351 functioning as a part of the conveyance path TP inside, a vacuum drying process group 352, in which vacuum dryers VD for vacuum drying the substrate S after the coating process are stacked, a heating process group 353, in which hot plates HP for heating the substrate S after the vacuum drying process are stacked, and a cooling process group 354, in which cool plates CP for cooling the substrate S after the heating process are stacked.

The housing 351 is provided between the second mounting table 341 and the coating unit 310. Further, in the Y direction, the housing 351 is sorted out for the vacuum drying process group 352, the heating process group 353 and the cooling process group 354. More specifically, the vacuum drying process group 352 is arranged on a (-X) direction side of the housing 351, and the heating process group 353 and the cooling process group 354 are arranged on a (+X) direction side. Further, a second conveyor robot TR2 is arranged movably in an X direction in the housing 351. This second conveyor robot TR2 is configured such that a hand (not shown) capable of holding the substrate S is accessible to the second mounting table 341, the vacuum dryers VD of the vacuum drying process group 352, the hot plates HP of the heating process group 353, the cool plates CP of the cooling process group 354 and the coating unit CT. Therefore, the second conveyor robot TR1 operates in response to a command from the controller for controlling the substrate processing apparatus 3, whereby the substrate S is reciprocated along the conveyance path TP between the second mounting table 341 and the coating unit CT and conveyed among the second mounting table 341, the vacuum dryers VD, the hot plates HP, the cool plate CP and the coating unit CT.

As just described, in this embodiment, two conveyor robots TR1, TR2 are provided. These conveyor robots TR1, TR2 cooperate to function as the substrate conveyor 360, whereby the substrate S received from the substrate carry-in/out device 2 is conveyed from the hot plate HP of the heating process group 332, to the cool plate CP of the cooling process group 333, to the second mounting table 341, to the coating unit CT, to the vacuum dryer VD, to the hot plate HP of the heating process group 353, to the cool plate CP of the cooling process group 354 and to the second mounting table 341 in this order and, thereafter, the substrate S is transferred to the substrate carry-in/out device 2.

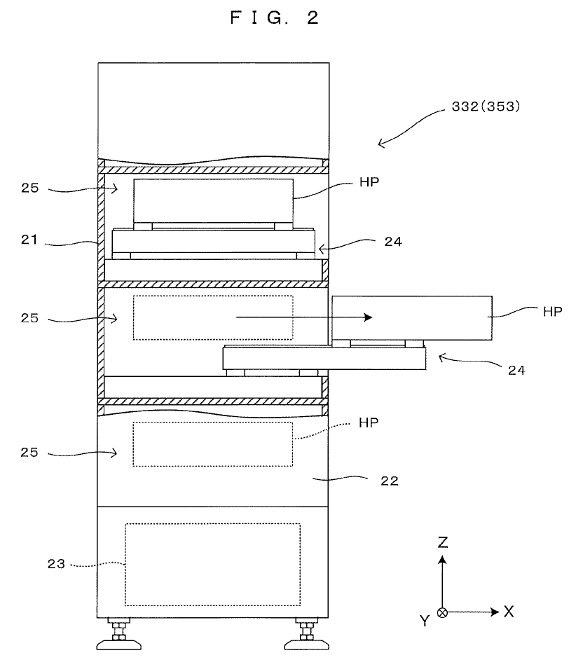

Out of constituent elements of the substrate processing system 1, components except the hot plates HP are conventionally known, whereas the hot plates HP have a specific configuration not found in conventional art, more specifically a configuration enabling a correction mechanism for correcting the warping of the substrate S to be switched between a correction posture and a separation posture. Accordingly, the components except the hot plates HP are not described below, whereas the configuration of the hot plate HP, a correction operation and a maintenance operation in the hot plate HP are described with reference to FIGS. 2 to 7.

FIG. 2 is a diagram showing the configuration of the heating process group, and a side wall is shown with an outer wall panel corresponding to two hot plates stacked in the vertical direction partially cut. The heating process group 332, 353 is provided with a body frame 21, three hot plates HP, an outer wall panel 22 mounted on the body frame 21 and a controller 23. Although the heating process group 332 is shown in FIG. 2, the heating process group 353 is also similarly configured. The inside of the body frame 21 is partitioned into multiple stages. The hot plates HP and the controller 23 for controlling three hot plates HP are stacked and stored in the multiple stages in those partitioned spaces.

A storage for storing the hot plate HP is provided with a pair of slide members 24. Although only one slide member 24 is shown in FIG. 2, the slide member is arranged also on a side opposite to the one slide member 24 across a storage space 25 for the hot plate HP. That is, the hot plate HP is arranged between the pair of slide members 24 in the Y direction.

The pair of slide members 24 constitute a mechanism for moving the hot plate HP along the X direction.

More specifically, the pair of slide members 24 move the hot plate HP between a processing position (e.g. a position where the hot plate HP in the first stage from above in FIG. 2 is stored in the storage space 25) where the hot plate HP is heated and a maintenance position (e.g. a position where the hot plate HP in the second stage from above in FIG. 2 is pulled out from the storage space 25) where maintenance is performed for the hot plate HP. Note that, since the configuration and operation of the pair of slide members 24 are described in JP 7597874B, these are not described in detail here.

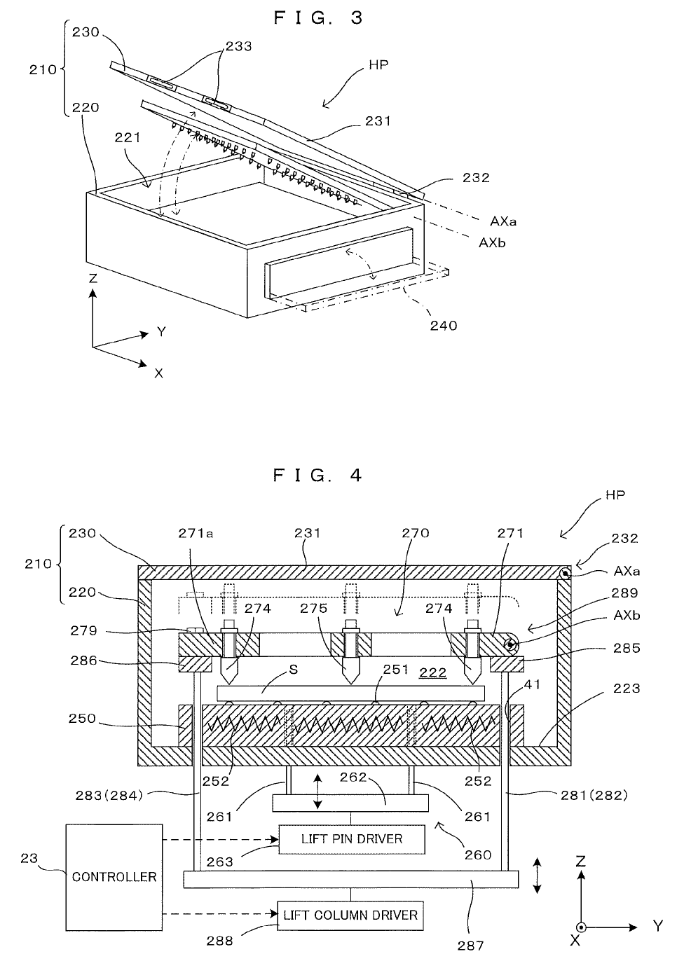

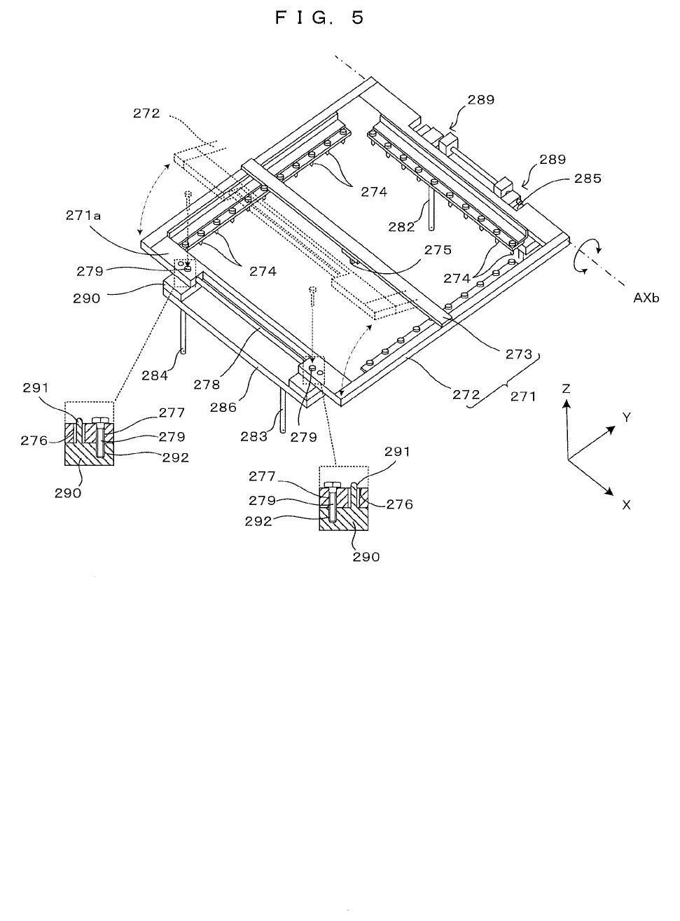

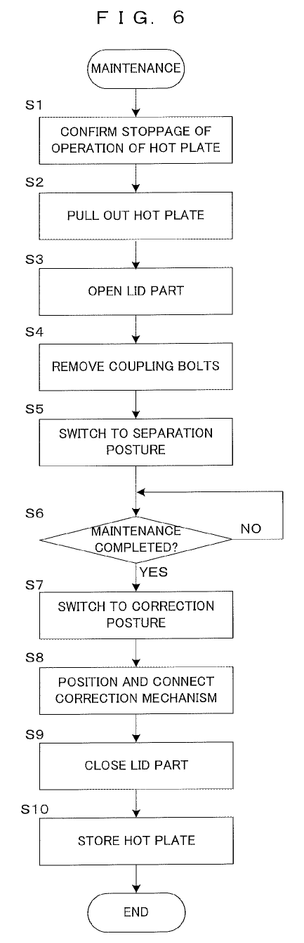

FIG. 3 is a perspective view showing the external structure of the hot plate HP (hot plate unit) as an example of the substrate processing apparatus according to the invention in a state where a lid member and a correction mechanism are opened for a maintenance operation to be described later. FIG. 4 is a schematic diagram showing the configuration of the hot plate HP. FIG. 5 is a perspective view showing the configuration of the correction mechanism. The hot plate HP is provided with a processing chamber 210 for storing the substrate S. By performing a processing in the processing chamber 210, a gas component vaporized by the heating process is prevented from scattering around and heat diffusion can be suppressed to enhance energy efficiency by covering around the heated substrate S. For these purposes, the processing chamber 210 includes a box-shaped chamber body 220 having an upper part open upward, a lid part 230 for closing an internal space 222 of the chamber body 220 by covering an opening 221 of the chamber body 220, and a shutter 240 for opening and closing an opening for substrate conveyance provided in a side wall of the chamber body 220. The chamber body 220 is a box body made of metal such as aluminum or stainless steel. Further, for weight saving, the lid part 230 can have, for example, a flush structure made of a metal material or may be made of carbon fiber reinforced plastic (CFRP) besides being made of a plate material made of metal.

The lid part 230 includes a flat plate-like lid member 231 having a planar size capable of covering the opening 221 from above, a hinge part 232 and handles 233 for opening/closing. As shown in FIG. 3, a (+Y) side end part of the lid member 231 is mounted on the chamber body 220 via the hinge part 232. The hinge part 232 swingably supports the (+Y) side end part of the lid member 231 in a cantilever state, and various known structures are applicable as such a structure. By such a configuration, the lid part 230 is swingable about a swing axis AXa parallel to the X direction shown by a one-dot chain line. This swing axis AXa corresponds to an example of a “second swing axis” of the invention.

In a state where an external force is not acting, the lid part 230 covers the opening 221 of the chamber body 220 by the own weight thereof. In this way, the processing chamber 210 is closed. Although not shown, an appropriate lock mechanism for fixing the lid part 230 in a closed state to the chamber body 220 is provided. In this way, the airtightness of the internal space 222 of the chamber body 220 is achieved.

Two handles 233 are attached to a (-Y) side end surface of the lid member 231. A worker can manually open and close the lid part 230 by holding these handles 233. To assist this manual operation, a gas damper (not shown) is attached to the lid part 230. Thus, if the worker opens the lid part 230 after the lid part 230 is pulled out in the X direction from the body frame 210 in the maintenance operation to be described later, an open posture of the lid part 230 is maintained by the gas damper. Further, if the worker pushes the lid part 230 downward, a swing speed is decelerated by the gas damper and the lid part 230 is gently closed. In this way, the gas damper has a function of assisting the opening/closing of the lid part 230. Note that this point also applies to a swing operation of a correcting/supporting part of the correction mechanism to be described later.

The shutter 240 is openably and closably mounted for an opening (not shown) serving as a conveyance path of the substrate S on a (+X) side surface of the chamber body 220. If the shutter 240 is closed in response to a close command from the controller 23, the shutter 240 is pressed against the side surface of the chamber body 220 via a packing (not shown). In this way, the opening functioning as the conveyance path of the substrate S is closed. On the other hand, in an open state of the shutter 240 shown by a one-dot chain line in FIG. 3, the substrate S can be transferred to and from outside via the opened opening. That is, the unprocessed substrate S held by the substrate conveyor robot TR2 (FIG. 1B) is carried into the processing chamber 210 via this opening. Further, the processed substrate S in the processing chamber 210 is carried out to outside by the conveyor robot TR2.

A heating plate 250 is provided on an inner bottom part 223 of the chamber body 220. A plurality of recesses (not shown) are provided in the upper surface of the heating plate 250, and spheres 251 having a diameter slightly larger than a depth of the recess are fit in the respective recesses. The substrate S can be supported from below by top parts of these spheres 251, and the substrate S carried in from outside is placed on the spheres 251 with a surface having a semiconductor chip and the like laminated thereon facing upward. In this way, the substrate S is positioned with a minute space called a proximity gap formed above the upper surface of the heating plate 250. In this specification, the position of the substrate S that is positioned in this manner and subjected to a heating process (i.e., the height position of the upper surface of the substrate S in the vertical direction Z) is referred to as the “heating position.” Further, a position in the vertical direction Z where the substrate S is temporarily put on standby to be transferred as described in detail later is called a “standby position” in this specification.

As shown in FIG. 4, a heater 252 is built in the heating plate 250 to perform the heating process on the substrate S positioned at the heating position. Power is supplied from the controller 23 for controlling the entire apparatus to the heater 252, whereby the heater 252 operates. In this way, the substrate S is uniformly heated by radiant heat from the upper surface of the heating plate 250. Note that the number and positions of the spheres 251 can be appropriately set according to the planar size and the like of the substrate S.

The hot plate HP is provided with an elevation mechanism 260 for smoothly transferring the substrate S between the heating plate 250 and the conveyor robot TR2. Specifically, a bottom plate of the chamber body 220 and the heating plate 250 are provided with a plurality of through holes extending in the vertical direction Z, and a lift pin 261 is inserted through each of these through holes. The lower end of each lift pin 261 is fixed to an elevating member 262. The elevating member 262 is supported movably up and down in the vertical direction by a lift pin driver 263. In response to an elevation command from the controller 23, the lift pin driver 263 operates to raise and lower the elevating member 262. In this way, the respective lift pins 261 integrally move up and down, and move between an upper position where the upper ends thereof project upward from the spheres 251 of the heating plate 250 and a lower position where the upper ends are retracted downward from the spheres 251.

FIG. 4 shows a state where the lift pins are at the lower position and, in this state, the upper ends of the lift pins 261 are separated from the substrate S. Thus, the substrate S is supported from below by the spheres 251 and the proximity gap is formed. In this way, the substrate S is positioned at the heating position. On the other hand, if the lift pins 261 are raised, the upper ends of the lift pins 261 contact the lower surface of the substrate S and push up the substrate S. In this way, the substrate S can be transferred by the conveyor robot TR2 (FIG. 1B) by being located at the standby position separated upward from the heating position. On the other hand, if the lift pins 261 not supporting the substrate S are raised to the standby position, the unprocessed substrate S can be carried to the standby position by the conveyor robot TR2. In this way, the substrate S can be transferred between the conveyor robot TR2 and the hot plate HP.

In this embodiment, a correction mechanism 270 is provided to uniformly heat the substrate S by correcting the warping of the substrate S. The correction mechanism 270 includes a correcting/supporting part 271. As shown in FIG. 5, the correcting/supporting part 271 includes a peripheral edge correcting/supporting member 272 and a center correcting/supporting member 273. The peripheral edge correcting/supporting member 272 is formed into a picture frame shape (or frame shape) to correspond to the substrate S having a rectangular shape. On the other hand, the center correcting/supporting member 273 is coupled to the peripheral edge correcting/supporting member 272 to couple a central part of a (+X) side part and a central part of a (-X) side part, out of four sides constituting the peripheral edge correcting/supporting member 272. The correcting/supporting part 271 configured as just described is movable up and down in the vertical direction Z. Specifically, through holes are provided in the vertical direction Z in four corner parts of the heating plate 250. Through holes are provided in the vertical direction Z also in the bottom plate of the chamber body 220 to correspond to these four through holes 41. Lift columns 281 to 284 are respectively inserted through the four through holes in respective corners of the heating plate 250. A first plate member 285 is mounted on the upper ends of two lift columns 281, 282 on the (+Y) side. A second plate member 286 is mounted on the upper ends of two lift columns 283, 284 on the (-Y) side. On the other hand, the lower ends of the lift columns 281 to 284 are fixed to an elevating member 287. This elevating member 287 is supported movably up and down in the vertical direction Z by a lift column driver 288. In response to an elevation command from the controller 23, the lift column driver 288 operates to raise and lower the elevating member 287. In this way, the lift columns 281 to 284 integrally move up and down to move the first plate member 285 and a second plate member 286 in the vertical direction Z.

The first and second plate members 285, 286 extend in the X direction. A pair of hinge parts 289 are mounted on both end parts of the first plate member 285, out of these, whereby a (+Y) side end part of the correcting/supporting part 271 is supported on the first plate member 285 swingably about a swing axis AXb. That is, the first plate member 285 swingably supports the correcting/supporting part 271 vertically below the swing axis AXb. The swing axis AXb is parallel to the swing axis AXa and extends in the X direction.

If moving toward the second plate member according to the swing of the correcting/supporting part 271, a (-Y) side end part of the correcting/supporting part 271 is locked to a pair of auxiliary plates 290 (FIG. 5) mounted on the second plate member 286. In this way, the correcting/supporting part 271 assumes a horizontal posture. In this correcting/supporting part 271 in the horizontal posture, the entire lower surface of the peripheral edge correcting/supporting member 272 faces the entire peripheral edge part of the upper surface of the substrate S from above, and a center of the lower surface of the center correcting/supporting member 273 is arranged to face a central part of the upper surface of the substrate S. As just described, the entire lower surface of the correcting/supporting part 271 corresponds to an example of a “peripheral edge facing region” of the invention and a center of the lower surface of the center correcting/supporting member 273 corresponds to an example of a “center facing region”.

As shown in FIGS. 3 to 5, a plurality of correction pins 274 are provided to hang vertically downward from the lower surface of the peripheral edge correcting/supporting member 272. Further, as shown in FIGS. 4 and 5, a correction pin 275 is provided to hang vertically downward from the center of the lower surface of the center correcting/supporting member 273. The correction pins 274, 275 correspond to examples of a “peripheral edge correcting member” and a “center correcting member” of the invention.

By setting the correcting/supporting part 271 in the horizontal posture, the respective correction pins 274, 275 face the peripheral end part and the central part of the substrate S. At this time, a positioning/fixing structure is adopted as shown in a partial enlarged view of FIG. 5 in this embodiment to set relative positions of the correction pins 274, 275 with respect to the substrate S in a horizontal plane and prevent the variation of the relative positions during the heating process.

A positioning pin 291 for positioning stands on each auxiliary plate 290, and an internally threaded hole 292 for bolt fastening is provided in each auxiliary plate 290. On the other hand, a through hole 276 is perforated at a position corresponding to the positioning pin 291 and a through hole 277 is provided at a position corresponding to the internally threaded hole 292 on the (-Y) side part of the correcting/supporting part 271. Further, on the (-Y) side part of the correcting/supporting part 271, a region sandwiched between the through holes 277 is cut and a handle bar 278 is provided in this region. Therefore, if the worker swings the correcting/supporting part 271 counterclockwise by holding the handle bar 278, the correcting/supporting part 271 covers the substrate S from above and tip parts of the correction pins 274, 275 face the upper surface of the substrate S as shown by solid lines in FIG. 5. With this posture kept, a correcting process is performed by lowering the correcting/supporting part 271 as described later. In this specification, the postures of the correcting/supporting part 271 and the correction pins 274, 275 for performing the correcting process are called “correction postures”.

On the contrary, if the worker swings the correcting/supporting part 271 clockwise, the (-Y) side part of the correcting/supporting part 271, i.e. an opposite swing axis side end part 271a, moves further upward than the opening 221 of the chamber body 220 and the correction pins 274, 275 are also separated from the substrate S. The postures of the correcting/supporting part 271 and the correction pins 274, 275 separated from the substrate S in this way are called “separation postures”. As just described, in this embodiment, the correcting/supporting part 271 can be switched between the “correction posture” and the “separation posture” by swinging about the swing axis AXb.

Further, in this embodiment, when a switch is made to the “correction posture”, the correcting/supporting part 271 is locked to the auxiliary plates 290 while the tip parts of the positioning pins 291 enter the through holes 276 and the through holes 277 are matched with the internally threaded holes 292 in the vertical direction Z. In this way, the correcting/supporting part 271 is positioned with respect to the second plate member 286. Thereafter, externally threaded parts of coupling bolts 279 for coupling and fixing are inserted into the internally threaded holes 292 via the through holes 277 and threadably engaged with the internally threaded holes 292, whereby the correcting/supporting part 271 is coupled to the second plate member 286 with the above positioned state maintained. Further, the respective correction pins 274, 275 mounted on the correcting/supporting part 271 are facing the peripheral end part and the central part of the substrate S, and preparation for the correction of the substrate S by the correction mechanism 270 is completed.

After this preparation for correction is completed, the lift column driver 288 operates to raise and lower the elevation member 287 in response to an elevation command from the controller 23. By these up-and-down movements of this elevation member 287, the correction pins 274, 275 collectively move vertically downward and can correct the warping of the substrate S. For example, if the substrate S is warped into a concave shape (or may be called a “trough shape”), i.e. if the peripheral end part of the substrate S is warped upward, this peripheral end part is pressed vertically downward by lower end parts of the correction pins 274 during downward movements of the correction pins 274, 275 and the warping is corrected by the correction pins 274. On the contrary, if the substrate S is warped into a convex shape (or may be called a “crest shape”), i.e. if the central part of the substrate S is more lifted up than the peripheral end part, the central part is pressed vertically downward by a lower end part of the correction pin 275 during downward movements of the correction pins 274, 275 and the warping is corrected by the correction pin 275. As just described, in this embodiment, regardless of whether the substrate S is warped into the concave shape or the convex shape, the warping can be reliably corrected.

The controller 23 for controlling the hot plate HP configured as just described is, for example, a computer and includes a processor such as a CPU and a memory electrically connected to the processor and configured to store a program. The processor executes the program stored in the memory, whereby the operation of each component of the hot plate HP is controlled. In this way, the correcting process and the heating process are performed.

As described above, according to this embodiment, the correcting/supporting part 271 is switchable between the correction posture and the separation posture by swinging about the swing axis AXb. In the separation posture, out of these, the correction pins 274, 275 are separated upward from the heating plate 250 with the opening 221 opened by opening the lid part 230. Thus, the worker can access the internal space 222 through the open opening 221. As a result, an access to the internal space 222 is facilitated and the efficiency of the maintenance operation can be improved as compared to conventional art in which a correction mechanism removal operation is essential for an access to the internal space 222.

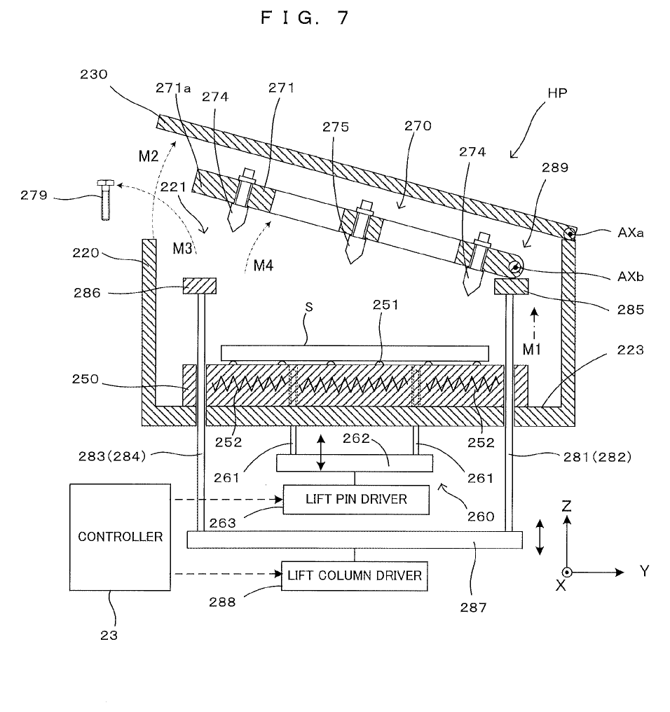

Further, in the above embodiment, the first and second plate members 285, 286 can be raised in the vertical direction Z while being kept in the correction posture. By a switch to the separation posture after these upward movements, the opposite swing axis side end part 271a moves significantly away from the opening 221 of the chamber body 220 as shown in FIG. 7. As a result, a gap for an access to the internal space 222 becomes larger and the easiness of the maintenance operation is enhanced.

Further, an arrangement relationship of the swing axes AXa, AXb is arbitrary as long as a condition that the swing axis AXa is arranged at a position higher than the swing axis AXb in the vertical direction Z is satisfied. By proximately arranging the swing axes AXa, AXb on the (+Y) side as in the above embodiment, the above gap can be set to be large, which is preferable.

Further, in the above embodiment, when a switch is made from the separation posture to the correction posture by the correcting/supporting part 271 swinging about the swing axis AXb, the relative positions of the correction pins 274, 275 with respect to the substrate S in the horizontal plane possibly vary. However, since the positioning pins 291 provided on the side of the second plate member 286 are inserted into the through holes 276 provided on the side of the opposite swing axis side end part 271a, the above relative positions can be constantly reproduced with high accuracy. As a result, the accuracy of the correcting process can be kept high.

Further, the correcting/supporting part 271 is coupled to the second plate member 286 by the coupling bolts 279 with the above positioned state maintained. Thus, the relative positions can be prevented from varying during the heating process, and the highly accurate correcting process can be stably performed. As just described, in this embodiment, the coupling bolts 279 are provided as an example of a “coupling member” of the invention.

Further, in this embodiment, the correction pins 274 for correcting the peripheral edge part of the substrate S are provided as in the apparatus described in JP 2020-47829A, but the correction pin 275 for correcting the central part of the substrate S is provided beside those. That is, the correction pins 274, 275 respectively correspond to examples of a “peripheral edge correction pin” and a “center correction pin” of the invention. Since these are both provided, the concavely warped substrate S and the convexly warped substrate S can be both corrected before the heating process and the stable heating process can be performed.

If the substrate S in the processing chamber 210 is broken or the cleaning of the internal space 222, the exchange of the correction pins 274, 275 or the like is necessary during the correcting process or the heating process of the substrate S, the maintenance operation is necessary. In this embodiment, since the lid part 230 and the correcting/supporting part 271 are respectively swingable about the swing axes AXa, AXb, the maintenance operation can be easily performed. The maintenance operation performed by the worker in this embodiment is described with reference to FIGS. 2, 4, 6 and 7 below.

FIG. 6 is a flow chart showing one embodiment of a maintenance method according to the invention. FIG. 7 is a diagram showing the postures of the lid part and the correcting/supporting part in one step of the maintenance method shown in FIG. 6. If the worker recognizes that the maintenance operation is necessary, the worker confirms that the operation of the hot plate HP requiring the maintenance operation, e.g. the hot plate HP in the third stage from above in FIG. 2, has stopped (Step S1). At this point of time, if the correction pins 274, 275 are in contact with the upper surface of the substrate S as shown by solid lines in FIG. 4, the worker may operate a tough panel (not shown) equipped in the controller 23 to perform a movement indicated by an arrow M1 in FIG. 7, i.e. to raise the correcting/supporting part 271 to the standby position (dotted line position in FIG. 4). Further, if a command to perform the maintenance operation is input via the touch panel from the worker, the controller 23 may automatically detect the above input and raise the correcting/supporting part 271 to the standby position (dotted line position in FIG. 4).

Following the stop confirmation of the hot plate HP, the worker pulls out the hot plate HP to the (+X) side as shown in FIG. 2 (Step S2). Following that, the worker opens the lid part 230 by holding the handles 233 (Step S3). In this way, the opening 221 of the chamber body 220 is opened as indicated by an arrow M2 in FIG. 7, and the worker can access the correction mechanism 270. Accordingly, the worker removes the coupling bolts 279 as indicated by an arrow M3 in FIG. 7 (Step S4). In this way, the correcting/supporting part 271 and the second plate member 286 are uncoupled, wherefore the worker holds the handle bar 278 (FIG. 5) and switch the correcting/supporting part 271 and the correction pins 274, 275 from the correction posture (FIG. 4) to the separation posture (FIGS. 3 and 7) by swinging the correcting/supporting part 271 clockwise as indicated by an arrow M4 in FIG. 7 (Step S5).

In this separation posture, the lid part 230 is opened and the correcting/supporting part 271 and the correction pins 274, 275 of the correction mechanism 270 are in the separation posture, wherefore the internal space 222 of the chamber body 220 becomes accessible through the opening 221 of the chamber body 220, particularly from the opposite swing axis side, i.e. from the (-Y) side. Then, the worker performs the maintenance operation such as the collection of the broken substrate, the exchange of the correction pins 274, 275 or the like via the opening 221. Then, if the maintenance operation is completed (“YES” in Step S6), the worker switches the correcting/supporting part 271 and the correction pins 274, 275 from the separation posture (FIGS. 3 and 7) to the correction posture (FIG. 4) by holding the handle bar 278 and swinging the correcting/supporting part 271 counterclockwise as shown in FIG. 5 (Step S7). At that time, after positioning the correcting/supporting part 271 to a position set in advance in the horizontal plane so that the positioning pins 291 are inserted into the through holes 276, the worker couples the correcting/supporting part 271 to the second plate member 286 by the coupling bolts 279 (Step S8).

Following that, the worker closes the lid part 230 by holding the handle 233 (Step S9). Further, the worker stores the hot plate HP into the body frame 21 (Step S10).

By performing the maintenance operation in such a procedure, the efficiency of the maintenance operation can be improved.

As described above, in this embodiment, the heating plate 250 corresponds to examples of a “substrate support” and a “heating process plate”. The correction pins 274 correspond to examples of a “correcting member” and a “peripheral edge correction pin”, and the correction pin 275 corresponds to examples of the “correcting member” and a “center correction pin” of the invention. The swing axes AXa, AXb respectively correspond to examples of a “second swing axis” and a “first swing axis” of the invention. The X direction corresponds to a “first horizontal direction” of the invention, and the Y direction corresponds to a “second horizontal direction” of the invention.

Note that the invention is not limited to the above embodiment and various changes can be added to the aforementioned embodiment without departing from the gist of the invention. For example, although the invention is applied to the hot plate HP provided with both the peripheral edge correction pins and the center correction pin as the correcting member, the invention can be also applied to the hot plate HP provided with only the peripheral edge correction pins.

Further, in the above embodiment, the correcting process is performed by integrally lowering the correcting/supporting part 271 and the correction pins 274, 275. However, the correcting process may be performed by raising the heating plate 250 or simultaneously lowering the correcting/supporting part 271 and the correction pins 274, 275 and raising the heating plate 250. That is, the warping of the substrate S may be corrected by raising or lowering at least one of the correcting/supporting part 271 and the heating plate 250 to bring the correction pins 274, 275 into contact with the upper surface of the substrate S supported on the heating plate 250.

Further, although the lid part 231 opens and closes the opening 221 by swinging about the swing axis AXa in the above embodiment, the opening 221 may be opened and closed by another driving method. For example, the lid member 231 may be slid in a horizontal direction to open and close the opening 221.

Further, although the invention is applied to only the hot plate HP in the above embodiment, the invention may be also applied to the cool plate CP including the heating process plate (substrate support). That is, application targets of the invention include heating process devices such as the hot plates HP and the cool plates CP.

Further, devices provided with a correction mechanism for correcting a substrate supported by a substrate support, e.g. a vacuum dryer equipped with a correction mechanism, are also included in the application targets of the invention.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

This invention can be applied to substrate processing apparatuses provided with a correction mechanism for correcting the warping of a substrate stored in an internal space of a chamber body and maintenance methods for substrate processing apparatus in general.

What is claimed is:

1. A substrate processing apparatus, comprising:
a chamber body having an opening opened upward and an internal space capable of storing a substrate;
a lid part configured to open and close the opening;
a substrate support configured to support the substrate from below in the internal space; and
a correction mechanism having a correcting/supporting part that is provided between the lid part and the substrate support and a correcting member that projects downward from the correcting/supporting part, wherein
the correction mechanism is configured to correct warping of the substrate by bringing the correction member into contact with an upper surface of the substrate supported by the substrate support, by raising or lowering at least one of the correcting/supporting part and the substrate support while the correction member remains in a correction posture facing the substrate support, and
the correcting/supporting part is provided so as to be swingable about a first swing shaft extending in a first horizontal direction, and is configured to be switchable between the correction posture and a separation posture in which the correction member is spaced upward from the substrate support with the opening opened by opening the lid part.

2. The substrate processing apparatus according to claim 1, wherein the correction mechanism includes:
a first plate member configured to support the correcting/supporting part swingably vertically below the first swing axis;
a second plate member provided away from the first plate member in a second horizontal direction orthogonal to the first horizontal direction and configured to support an opposite swing axis side end part of the correcting/supporting part on a side opposite to the first swing axis in the second horizontal direction when the correcting member is set in the correction posture; and
an elevation member configured to move the first plate member and the second plate member in a vertical direction.

3. The substrate processing apparatus according to claim 2, wherein:
a positioning pin stands from one of the second plate member and the opposite swing axis end part and positions the correcting/supporting part and the correcting member with respect to the second plate member by being engaged with the other in the correction posture.

4. The substrate processing apparatus according to claim 3, further comprising:
a coupling member for coupling the second plate member and the correcting/supporting part positioned with respect to each other.

5. The substrate processing apparatus according to claim 1, wherein:
the lid part includes a lid member capable of covering the opening and is configured to open and close the opening by swinging the lid member about a second swing axis parallel to the first swing axis and arranged above the first swing axis in a vertical direction.

6. The substrate processing apparatus according to claim 5, wherein:
the first swing axis and the second swing axis are arranged on one side of the chamber body in the second horizontal direction.

7. The substrate processing apparatus according to claim 1, wherein:
the correcting/supporting part has a peripheral edge facing region facing a peripheral edge part of the upper surface of the substrate supported on the substrate support in the correction posture, and
the correcting member includes a peripheral edge correction pin projecting downward from the peripheral edge facing region.

8. The substrate processing apparatus according to claim 7, wherein:
the correcting/supporting part has a center facing region facing a central part of the upper surface of the substrate supported on the substrate support in the correction posture, and
the correcting member includes a center correction pin projecting downward from the center facing region.

9. The substrate processing apparatus according to claim 1, wherein:
the substrate support is a heating process plate configured to heat the substrate.

10. A maintenance method for substrate processing apparatus according to claim 1, the method comprising:
opening the opening,
switching the correcting/supporting part to the separation posture by swinging the correcting/supporting part about the first swing axis, and
performing a maintenance operation by accessing the internal space through a gap formed between an opposite swing axis side end part of the correcting/supporting part and the opening.
